(19) United States
(12) Patent Application Publication
(10) Pub. No.: US 2025/0021530 A1
(43) Pub. Date: Jan. 16, 2025

(54) RECONFIGURABLE DECLARATIVE GENERATION OF BUSINESS DATA SYSTEMS FROM A BUSINESS ONTOLOGY, INSTANCE DATA, ANNOTATIONS AND TAXONOMY

(71) Applicant: Graph Research Labs Limited, Auckland (NZ)

(72) Inventor: Dougal Alexander Watt, Auckland (NZ)

(21) Appl. No.: 18/713,687

(22) PCT Filed: Nov. 25, 2022
(86) PCT No.: PCT/NZ2022/050157

§ 371 Date: May 27, 2024

(30) Foreign Application Priority Data
Nov. 25, 2021 (NZ) 782698

(51) Int. Cl. G06F 16/21; G06F 30/20

(52) U.S. Cl. CPC G06F 16/211; G06F 30/20

(57) ABSTRACT

A method of defining and managing data integration, data storage, programmatic data access and data serving is described, the method comprising: retrieving from memory a set of semantic information models; displaying for a user a set of semantic information models; receiving a selection from the user; based on the selection assembling canonical specification schema artifacts, the canonical specification schema artifacts used to define data integration, storage, programmatic access and serving of data; generating canonical specification schema artifacts, used to define data integration, storage, programmatic access and serving of the data; displaying for the user the canonical integration schema artifacts; receiving a selection from the user whereby the canonical schema is mapped to data sources, and sending the appropriate schema artifacts to appropriate Data System endpoints and configuring the endpoints for operation. A system implementing the method is also described.

### FIELD

The present disclosure is in the technical field of Information Technology (IT). More particularly, aspects of the present disclosure relate to systems, methods, computer science ontologies, taxonomies and their associated metadata and apparatuses that are collectively used to declaratively create and manage integrations, data storage and access systems, and Application Programming Interfaces (API), and using the same mechanism, propagate Schema and data to other business systems.

### BACKGROUND

Application Programming Interfaces (API's), GraphQL interfaces and event/message based Topics are some of the most common and usable integration technologies for accessing data and business logic in Internet-connected application systems within and between companies (so-called ‘Systems of Record’).

The current state of the art for creating and managing these integrations involves many different software tools and roles, stitched together with manual workflows to create and manage integrations. This complexity and toolset results in an ‘imperative’ approach to building integration and API's, where the various human roles must coordinate across workflows, tools and software code, to tell the different systems how they have to build integrations, as described below:

### Roles Include

Database Administrators responsible for workflows that create and manage data stores and their associated data schema in Systems of Record
Application Developers responsible for workflows that create and manage business logic in Systems of Record
Integration Developers responsible for workflows that map the needs of Application Developers and Database Administrators on to API definitions, including data and business logic processing within the created API's.
Security Specialists responsible for mapping these resources to entitlements controlling who can access what resources through the API

and specialist software tools that include:
Integration Middleware used to ingest data into a database system for storage and later serving via an API. These tools can be configured to support data definitions via standard data structures (e.g. Apache Avro Schema), which ensure ingested data conforms to a pre-specified data schema.
Various Data Modelling tools used for creating the data formats used by the different roles, including data file formats used by the API Generator, Database Server, and Integration Middleware. However, these activities typically require separate tools and are disconnected from each other, requiring manual synchronisation between the Database Administrator, Application Developer and Integration Developer. They also not use the advanced data standards in this invention to concurrently create a plurality of integration types that link together the database schema and API contract definitions
Database management systems, used for storing data, most often in conformance to a database schema that specifies the structure of stored data, but typically not the semantics or meaning of data
API generator—takes an API specification and creates an API server to serve data from a database, typically using the REST architectural style, which relies on a complex tool chain with data modelling tools and integration middleware. Compared to this invention, API generators require extensive manual work to link them to databases, do not support Semantic Graph Databases or declarative generation from ontologies, annotations, and associated taxonomies Programmatic data mappers, allowing for mapping of typical imperative coding languages such as Java, on to underlying data sources. These have typically been created to use Relational Database Management Systems, and in contrast to the current invention, do not support Semantic Graph Databases via declarative generation.

In contrast, this invention uses a declarative approach, whereby a single user tells the system what integration outcome they want to achieve through selection and refinement of pre-defined advanced ontology data structures and industry-standard integration, data storage and data management approaches. This integration outcome is represented as a user-specific configuration of the pre-packaged Ontologies and is subsequently processed by a declarative generator system to generate the necessary configuration data structure artefacts appropriate for each element of the integration solution, for example: YAML API contract artifacts for generating an API Server, RDF or SQL database schema artifacts for generating a database server, and Avro schema artifacts for integration middleware.

The current integration landscape has little or no automation across the different workflows, roles and tools required to create and manage a complex data system, resulting in complex, time consuming and error prone efforts to manually create and deploy APIs and connect these to Systems of Record and integration middleware. This also makes it complex and expensive to change, especially as this landscape evolves over time.

This complexity is driven by the imperative nature of the tools described above, the manual workflows required, and the socio-technical nature of integration within organisations that requires many interactions across different individuals with different levels of specialisation and domain expertise, and many different software tools each requiring a separate schema to define the data managed by those tools. With such levels of complexity, it is inevitable that the meaning of transacted data loses synchronisation across the total system, causing data quality errors, and requiring considerable manual effort to trace and rectify divergent meaning.

Specifically, additional Data System landscape complexity arises due to proliferation of API's within organisations. This is driven by external factors, such as more commercial off the shelf applications being purchased and used by organisations (e.g. Software as a Service) that provide their own pre-built API's, and internal factors such as demands for customer-centric business apps requiring organisations to create such apps to access organisational resources through API's and GraphQL and message or event based integration.

As the number of and need for API's increases, so do the number of API-driven connections back to organisational Systems of Record. Often one API can access many different Systems of Record, increasing total landscape complexity.

Further increases in total complexity occur all the time, as organisations keep adding more data silos as they acquire and use more data and applications. Each of these new data generating systems and databases will in turn require construction of additional API's to access and update these resources. This also contributes to more errors and risk in the current landscape as more API's are added or deleted.

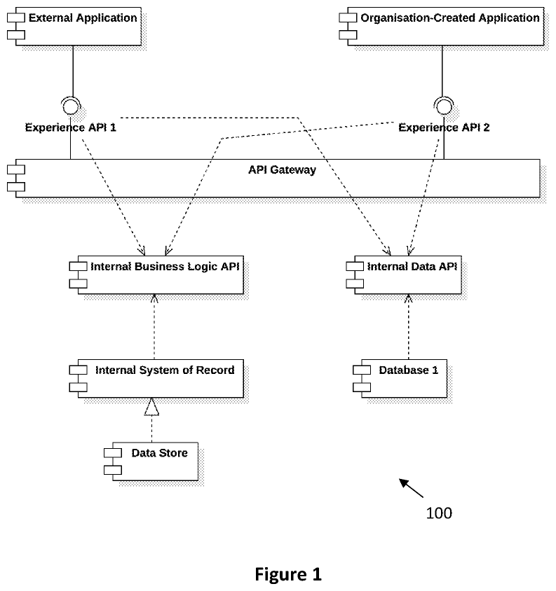

A related issue occurs when accessing systems via API's. Here, the definitions of data in the backend Systems of Record and databases are very different from the data expressed through API's. For example, so-called ‘Experience API's’ mediate between API's accessing backend resources and the specific, highly tuned data needs of front end apps such as Mobile apps. This often requires aggregating data from multiple back end systems into the Experience API's, which often requires processing through other API layers such as Domain and Business API's in order to mediate the meaning of the data across these layers. Skilled human resources and API management tools are required to manage this difference, keep the API's in sync with the back end business systems, and translate and transform inbound and outbound data across the different layers. FIG. 1 depicts a simplified view of this complexity 100.

Further complexity arises because as the number of API's increases, the number of requests for resources to the backend Systems of Record also increases, placing increased performance demands on these systems that may result in performance degradation for both the System of Record and the front end apps. In addition, if a back end System of Record is updated or needs to be replaced, the API's and their calling apps will all have to be updated to comply with the new/re-defined resources provided by the System of Record, which can be an extremely expensive and time consuming endeavour.

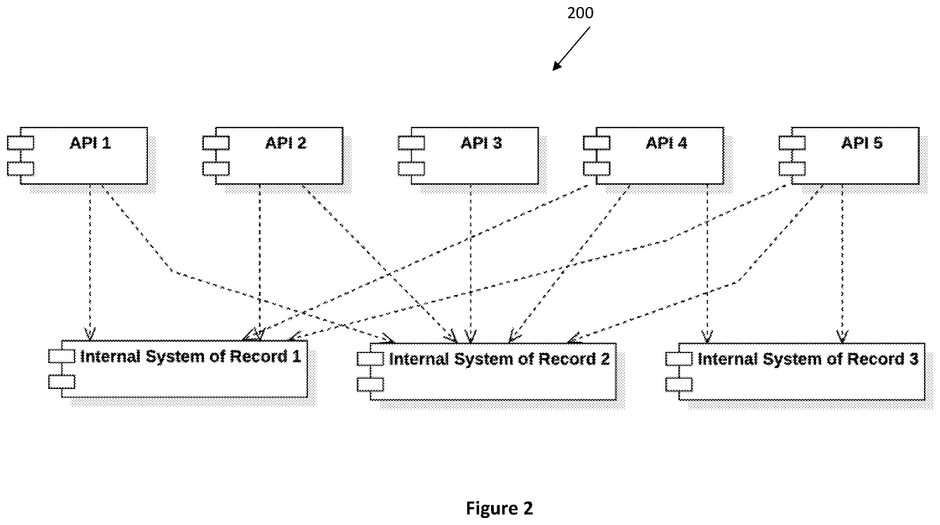

This ‘close coupling’ is depicted in the FIG. 2, showing typical ‘spaghetti wiring’ 200 between Systems of Record and calling API's that are directly wired to these systems.

Finally, increased need for regulatory compliance has driven different industry sectors to attempt to comply to regulatory or de-facto industry standards, such as the Open Banking movement for transparency and account portability in banking. Such standards are complex, requiring considerable engineering work to comply with across API, database and integration systems, and they often have very limited guidance in how to implement the standard and map existing business systems data and resources on to the standards.

Collectively, these issues result in a human and technology landscape that becomes exponentially harder to manage over time. Much of the knowledge required to design and operate, then change this landscape will be distributed across API's, databases, integration middleware and Systems of Record, and in poorly documented software code, hence obscured from the human actors responsible for managing the data system. Over time, this renders the totality of the system unknowable by individuals and even teams.

Further, the close coupling between API's and resources, plus the unknowability of the landscape will render it extremely brittle to any change at any point, such as when Systems of Record become too old and need to be replaced. This often results in organisational paralysis, where change in the landscape is deferred as any one change can have a potentially catastrophic impact in dependent systems that may threaten business continuity.

A key driver of this invention is to address these complex issues in a novel way, using a unique combination of advanced semantic ontology information structures in a declarative approach to reduce the overall complexity of the required Data System landscape. Because these artifacts have been generated from a single definition in the ontology, they are linked together, which ensures the meaning of the information that flows from integration into a database and out through an API is always consistent, while also supporting complex industry standards as discussed in the next sections.

### SUMMARY

According to one example embodiment there is provided a method of data model management and generation of data storage, data integration, programmatic data access, and data serving:
retrieving from memory a set of semantic information models;
displaying for a user a set of semantic information models;
receiving a selection from the user;
assembling a canonical sub-set of semantic information models based on the selection and targeted at the subsequent generation step;
generating canonical specification schema artifacts, used to define a graph database schema, data integration schema, object-based programmatic data access schema, and data serving via an API schema;
displaying for the user the canonical schema artifacts;
generating the required graph database server and API server, and sending these the appropriate schema artifacts;
receiving a selection from the user whereby the canonical graph database schema is mapped to system of record data sources;
sending the appropriate integration schema artifacts to the appropriate integration endpoints and configuring the endpoints for operation; and
generating additional data access code bound to the semantic graph database schema for programmatic access to the subsequently data stored in the graph database via API's.

According to an example the semantic information models define the options for all elements of the data system, comprising data integration, storing, programmatic access, and serving of this data.

According to an example the options for the data system consist of:
a. classifications and business rules for data, relationships to other classified data elements, and any industry standards pertaining to the data;
b. categories and configurations of the different types of integration and serving that can apply to a;
c. categories and configurations of the different database storage systems, programmatic access systems, and data source mappings that apply to a; and
d. categories of allowable methods (rules) of assembling and configuring the total data system that apply to a, b and c.

According to an example the semantic information models are defined as ontologies, annotation models and taxonomies, themselves embedded within the ontologies.

According to another example embodiment there is provided a system implementing the method.

According to another example embodiment there is provided a computer-readable storage medium having embodied thereon a computer program configured to implement the method.

### BRIEF DESCRIPTION

The description is framed by way of example with reference to the drawings which show certain embodiments. However, these drawings are provided for illustration only, and do not exhaustively set out all embodiments.

FIG. 1 shows the current state Experience API's accessing internal APIs and business logic.

FIG. 2 shows the current state ‘spaghetti wiring’ across Systems of Record and Calling API's.

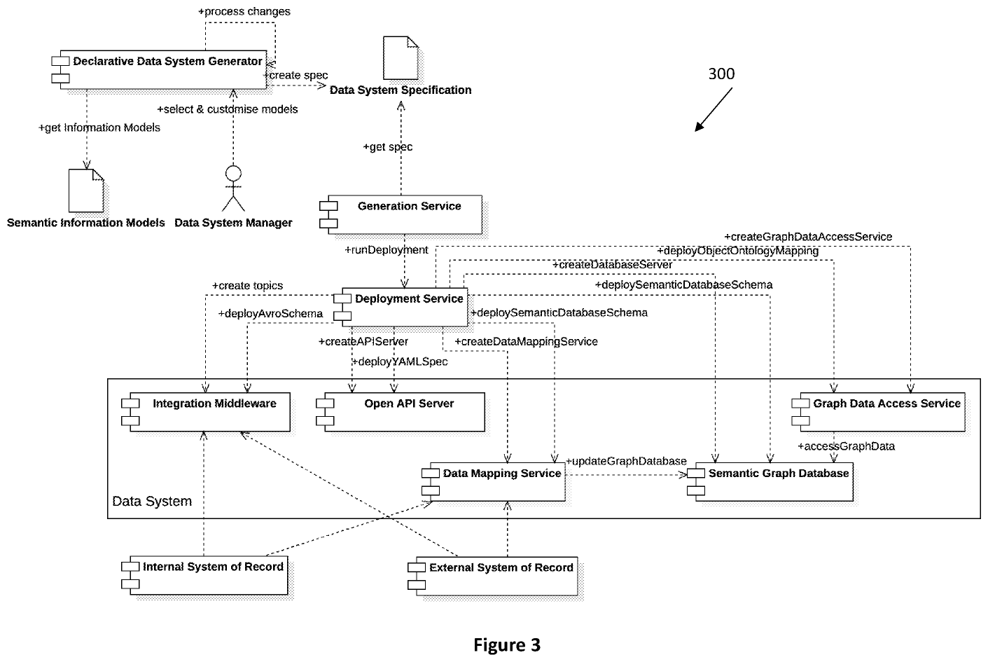

FIG. 3 shows the invention mechanism.

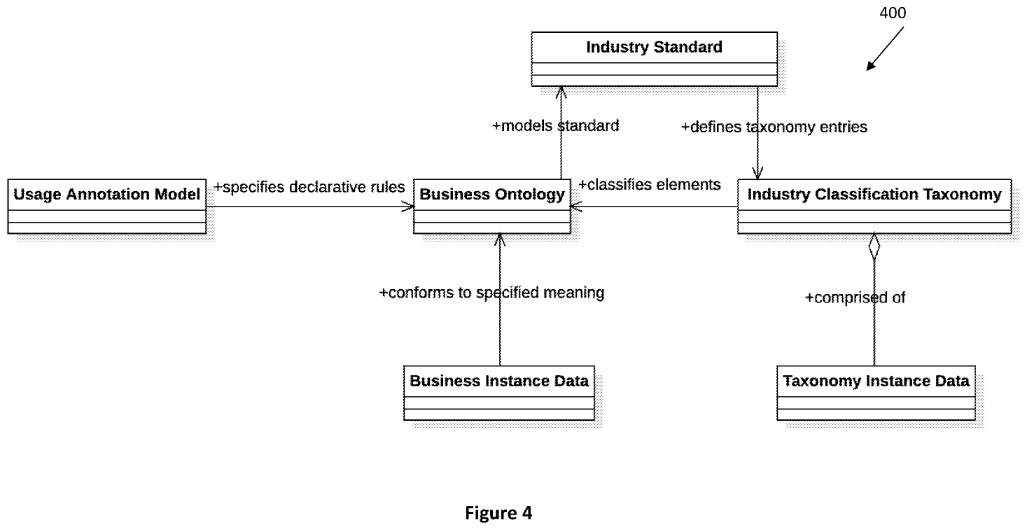

FIG. 4 shows the invention meta-model.

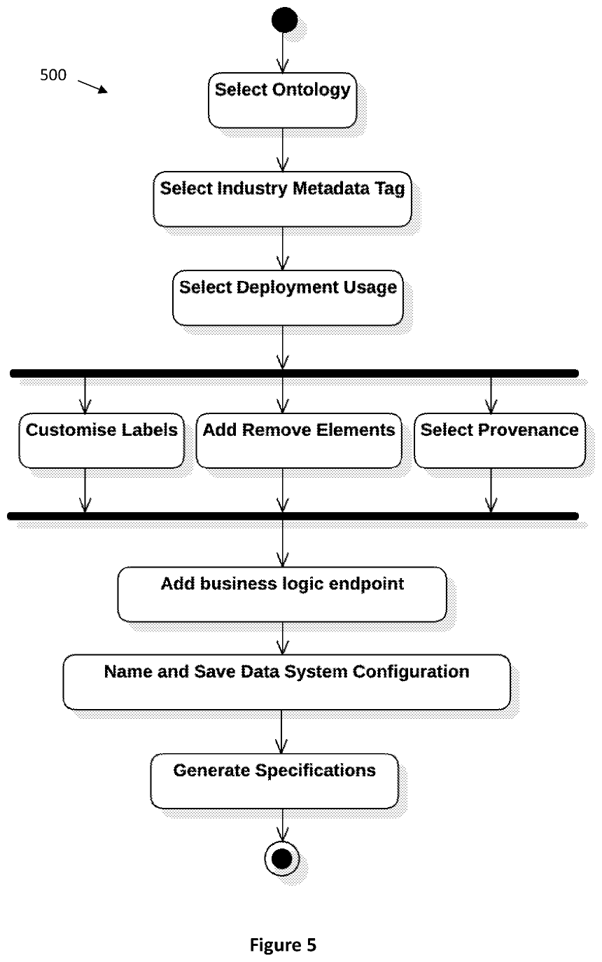

FIG. 5 shows the configuration workflow.

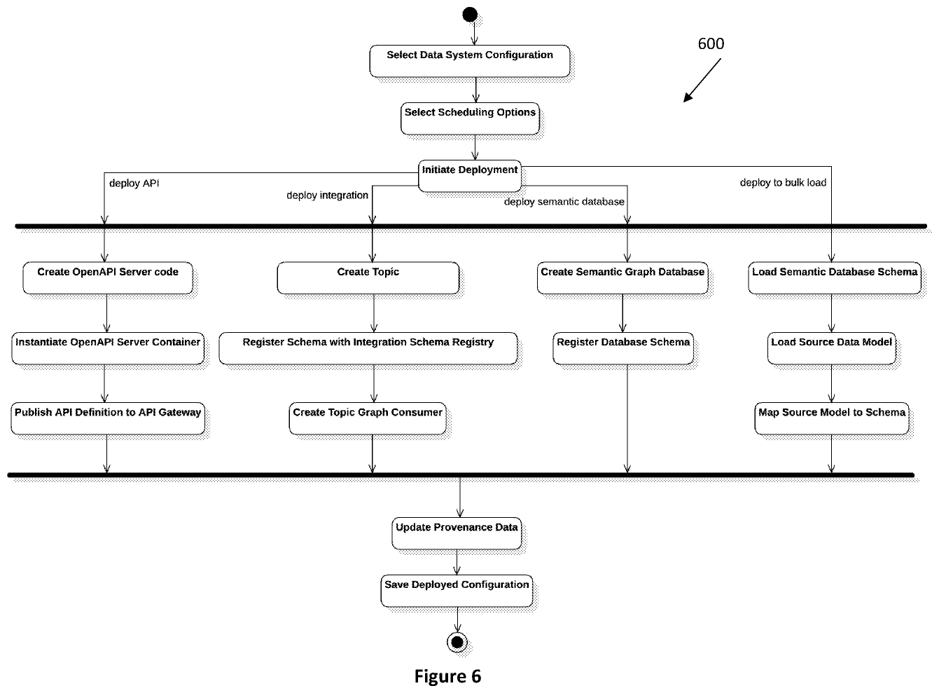

FIG. 6 shows the deployment workflow.

### DETAILED DESCRIPTION

The need to make explicit the knowledge of a Data System, whereby such a system comprises the ability to integrate data, store data, programmatically access data, and serve data, across this landscape is a key driver of the current invention. It proposes a new and more efficient approach to managing this complexity and transforming the total landscape into a knowable state by replacing the traditional manual approach with a declarative approach consisting of, at a high level, a Mechanism and an Information Model that utilises a semantic information model.

To resolve these issues, this invention proposes a new Method and System that has been developed to overcome these problems. The system guides a Data System Manager responsible for managing this landscape, through declaring what their Data System should achieve, and then the system creates the required software systems, and populates these with the information structures (schema) necessary to support this.

The invention is comprised of a computer system mechanism that manages the build, and operation of the total Data System, in accordance with a semantic information model, user selections, and workflows. The end result is that this invention seeks to remove much of the current complexity of additions and changes of data integration, storage, access and serving systems, and render the total landscape discoverable and knowable for a single user.

### Mechanism

The mechanism used in this invention is depicted at a high level in FIG. 3, 300.

Here, a Data System Manager role is tasked with creating or updating some aspect of a Data System within an organisation. For example, this may consist of, but is not limited to, creating or updating a REST API, managing a database storage schema, or changing a message based integration job in Integration Middleware.

The Data System Manager role accesses a Declarative Data System Generator tool that has loaded into it a set of Semantic Information Models (described below). These models define the totality of options for specifying the meaning and operation of all aspects of the Data System, which consist of:
1. classifications and business rules for data, relationships to other data, and any industry standards pertaining to the data;
2. categories and configurations of the different types of data integration, data storage, programmatic access to data, and data serving that can apply to 1; and
3. categories of allowable methods (rules) of assembling and configuring the total Data System that apply to 1, and 2.

Based on the Data System Manager's selections, the Declarative Data System Generator assembles the information models and selections using pre-defined mappings for each category of technology (e.g. Integration Middleware, API's), and processes them into specification artifacts, that define the meaning of data and all aspects of the operation of the data systems, including but not limited to:
API definitions (e.g. YAMI, GraphQl Schema)
Integration Middleware definitions (e.g. Kafka Schema Registry schema)
Database storage schema and constraints (e.g. RDFs/OWL schema for a Semantic Graph Database Server and Data Mapping Service)
Graph Data Access Service (e.g. mappings between Java software code Objects and the Ontology).

It then loads these into a Deployment Service, which understands the different Data System technologies under management of the Data System such as REST API's or Kafka Topics. The Deployment Service then pushes the appropriate schema artifact to the appropriate Data System and configures them for operation if they currently exist, or if they have not been previously created, it deploys and configures the required data system e.g.
YAML definitions->API Gateway
GraphQL schemas->GraphQL Server
Kafka Schema Registry definitions->Kafka Schema Registry and matching Topics
Semantic Graph Database Schema definitions->RDF/OWL Semantic Database Server and Data Mapping Service.

The invention also uses the specification artifacts deployed into the Integration Middleware and Semantic Graph Database to retrieve data from existing Systems of Record (including application systems and databases) using a plurality of technologies in common usage including but not limited to message passing/event based systems, such as Kafka, and bulk data loading systems, such as OpenRefine. For message/event based integrations this consists of e.g. Avro schema definitions paired to named topics, which specifies the format of data ingested via this approach. For bulk data loading systems, this occurs within the Data Mapping Service via automatically or user generated mappings, that specify how data from Systems of Record is mapped on to the Semantic Graph Database Schema. In the case of both integration approaches, the invention conforms the inbound data to a Semantic Information Model, and stores this in the Semantic Graph Database as discussed in the Instance Data section below.

For cases where software code requires access to data, the invention also generates a Graph Data Access Service that provides a mapping layer between object representations of data, and the underlying Semantic data representation used by the Ontology and Semantic Graph Database System.

The novel use of semantics in the form of describing the Data System landscape in OWL 2 ontologies, annotations, and taxonomies, allows this invention to build a rich representation of the totality of the Data System landscape existing within an organisation. It builds explicit relationships and data rules across the different data, systems, integration methods and industry standards in an organisation, and allows these to be modified at will at run time, instead of the current state where it is spread implicitly across roles, technologies and data and typically once built is crystalised and hard to change.

### Semantic Information Models

The Declarative Data System Generator takes as input a Semantic Information Model consisting of four key data structures as follows:
1. Business Ontology—an advanced data structure used to define the schema, rules and meaning of enterprise data for both generic common types of data and in support of industry-specific data standards, using the OWL 2 standard language;
2. Usage Annotation Model—metadata independently categorising Ontology elements by how they will be used during declarative generation of the Data System, and what industry standard the annotated element supports. This model allows for differential deployment and update of the Data System landscape without changing the other Semantic Information Models;
3. Business Instance Data—the data integrated from Systems of Record and stored in the Semantic Graph Database, that conforms to the Business Ontology, and will be served or programmatically accessed as needed;
4. Industry Classification Taxonomy—used to categorise the Business Ontology elements without affecting the underlying semantics represented in the Ontology, using definitions and classifications defined in Industry Standards.

These data structures are depicted in FIG. 4, 400 as a meta-model (an overarching, organising model).

### Business Ontology

The Business Ontology defines a canonical model of the meaning and structure of enterprise data, and its relationships with other data. The Ontology is constructed in accordance with standards such as OWL 2.0 and SHACL, and is used to classify data that will be mapped from different systems that may seem to be highly variable or different, into a canonical model that allows for arbitrary extension and interrelationship across data sets.

The Business Ontology may be composed of other sub-models as needed to support different industry standards, including a model for the separate capture of Provenance data, itself linked back to the other Business Ontology elements and deployed systems. Such a model records how the Business Ontology is deployed into use and the activities, agents and entities that interact with its data. This allows for arbitrary extension and evolution of the ontology, or custom-tailored ontologies to support specific standards, while preserving common semantics for shared, long lived types of data. Further sub-models may include user customisations of the other models, such as extensions to support management of additional data and data types.

In addition to categorising enterprise data, the Business Ontology provides the schema for storing this data in the Semantic Graph Database.

A unique aspect of this invention is that the behaviour of the generated Data System can be modified at run-time (i.e. during operation) by assembling any combination and multiplicity of the Business Ontology, Usage Annotation Models and Industry Classification Taxonomies, along with user selections of said artefacts.

Another unique aspect is that all artifacts are linked together into a single system of shared meaning, across all parts of the Data System, including the Provenance Ontology and captured data.

### Usage Annotation Model

Each Business Ontology element has appended to it metadata, which categorises that element by multiple dimensions of usage which controls the operation of the Declarative Data System Generator (e.g. create an API endpoint for a set of Ontology classes), and also categorises that element by a given industry sector standard (e.g. the Accord Insurance Industry reference architecture standard) and version of that standard.

Multiple categorisations are possible to allow the invention to concurrently support many different standards, versions, and usages within those standards.

Because this model is linked to the Business Ontology elements, or groups of elements, it defines allowable Data System deployment methods at an aggregate and granular level of control. For example, an industry standard for integrating automotive sales data may specify that Product/Car supports all the standard GET, PUT, POST, DELETE and PATCH REST HTTP Methods. If the user has selected this standard, the Usage Annotation Model entries for Product/Car will be included in their selection, and show as annotations on that class, allowing the user to further select or de-select these to refine what form the declarative generation and deployment will take (e.g. only deploy GET API methods).

Another unique aspect of this invention is that the Usage Annotation Model is maintained as a separate artifact from the Business Ontology and imported into it at run-time. This allows it to be extended as standards evolve by adding additional entries to support evolving or new data systems and industry standards, without requiring changes to the Business Ontology or Industry Classification Taxonomy.

### Industry Classification Taxonomy

Different industry standards frequently provide arbitrary classification approaches to data. For example, the insurance industry classifies insurance risk according to several schemes such as ‘Policyholder Classification’, which classifies the type of policyholder such as Individual or Commercial, and ‘Policyholder Identification Code Set’, which classifies aspects of the policyholder such as economic activity. Rather than creating separate ontology structures for these industry-specific classifications, specific Industry Classification Taxonomies can be created on a per-industry basis to support these classification approaches.

This provides a high degree of flexibility and ‘pluggability’ between supported industry standards and the Business Ontology. When used in concert with the Usage Annotation Model, the Data System Manager can select an industry classification taxonomy and apply this to other ontology elements outside of that industry standard, then separately specify on a per ontology element basis how the deployment generator will process the taxonomy entries. For example, they can select the ‘Policyholder Classification’ taxonomy defined in the Lloyds CDR standard and generate an API endpoint for this using an Insurance CDR ontology, and also use this in a different, General Insurance Ontology to generate only a Kafka event Avro Schema and topic.

The runtime behaviour of the whole Data System can also be modified simply by selecting which industry standard to deploy from the options in the Usage Annotation Model. For example, this allows the Data System Manager to specify deployment of the ‘Insurance CDR’ industry standard to generate an API and Semantic Graph Database schema, and the system will build and deploy this usage configuration. If a subsequent update to this standard is released that incorporates new or updated taxonomy classifications, the system can re-build the total Data System with no user intervention required.

### Business Instance Data

This data structure is used to store the data integrated from Systems of Record in the Semantic Graph Database in a schema that conforms to the Business Ontology using the Resource Description Format (RDF) data specification standard.

Business Instance Data is ingested either via the Integration Middleware or via the Data Mapping Service. In each case, inbound data is conformed to the Business Ontology before being stored as RDF in the Semantic Graph Database.

The combination of using declarative generation via the Business Ontology with the Usage Annotation Model and Industry Classification Taxonomy to define the meaning and format of Business Instance Data is unique in the field of Data Systems.

In contrast to existing approaches to managing a Data Systems landscape, the loose coupling and extensibility of the different Semantic Information Models used in current invention allows for a high degree of flexibility in supporting different industry standards deployed via different data management technologies and supporting different usage patterns, while allowing for runtime changes to the Data System and multiple concurrent versions of said deployments and standards.

### Workflow

The invention operates through two flows, which dramatically simplifies the current approach to managing a Data System:
1. Configuration Workflow—sets up the Semantic Information Model elements for later use in the Data System
2. Deployment Workflow—creates and deploys all technical systems and configurations comprising the total Data System.

### 1. Configuration Workflows

The configuration workflow shown in FIG. 5, 500 allows a user to configure and save the different information model elements into a form suitable for declarative generation of a Data System.

Here the user selects the Business Ontologies available in the system to allow them to integrate and access and serve conformed data.

Not shown is the mechanism that loads the ontologies into the system. Multiple ontologies can be made available via this mechanism.

Once the user has selected the Business Ontology, the system displays the Usage Annotation Model elements available, and the user selects the appropriate metadata tags corresponding to a) standards they wish to support and b) how they wish to deploy these. For example, if they wish to create an API for use in banking, they will first select the Industry/Banking metadata tag then the API tag.

The system then displays only those ontology elements that have been tagged with that metadata. If a class contains a relationship to another class that is not annotated with these tags, the relationship and its destination class will not be displayed.

The user can also further customise their selection by removing selected elements that conform to that metadata tag, and by modifying pre-defined metadata elements so selected, such as changing the Preferred Label that will display in an API. Additional options may also be presented allowing the user to extend their selection, to define additional data to be stored, integrated and accessed. These extensions are linked to the Business Ontology at the user-selected Ontology Class and defined as small sub-ontologies of the main Business Ontology. They can also choose whether they create a separate graph of provenance data (e.g. how the Data System is deployed and used).

Some industry standards (e.g. BIAN) allow for business logic operations on data. In such cases, this workflow will allow the user to annotate that element of the Business Ontology with a link to the endpoint that will action that business processing logic in one or more Systems of Record.

Once these modifications are complete, the user names and saves their new data System Configuration, and the system stores this configuration and generates the different specification artifacts for later use the Deployment Workflow.

### 2. Deployment Workflow

The deployment workflow illustrated in FIG. 6, 600, is intended to deploy the specification artifacts into usage within technical Data Systems, so they are ready to ingest, store, access and serve data.

Here the user selects a previously stored Business Integration Configuration to generate or update their Data System.

The user can then select options to schedule when the deployment will occur.

Next, the system initiates deployment of selected elements of the Data System, depending on the options selected in the Data System Configuration.

Next, the system chooses one or more optional pathways depending on the metadata and selections made in the previous step.

If the configuration includes API usage metadata, the system will create an OpenAPI Server and instantiate a container for this code, for deployment. Options exist to further automate the deployment step in further iterations of this invention.

The system will then publish the API definitions to an API Gateway (previously added as a configuration option in the system), which provides a single access point for external internet calls in to the organisation and enforces authentication, authorisation and entitlement controls over access to the resources defined in the API.

The parallel or alternative Deploy Integration flow will first generate an integration Topic on integration middleware that supports schema, such as Kafka (previously added as a configuration option in the system).

Next the system registers the Integration Schema with the Integration Schema Registry used by the Topic system (previously added as a configuration option in the system).

The system then creates a matching Topic Graph consumer to read data from the Topic and store this in the Graph Database in the format specified by the Database Schema.

The parallel or alternative ‘Deploy Semantic Database’ flow creates a Semantic Graph Database if one doesn't exist, to store integrated data.

Next, the system registers the Database Schema with the Semantic Database if it supports this ability.

The parallel or alternative ‘Deploy to Bulk Load’ flow, prepares the Bulk Loading tool for usage by loading the Semantic Database Schema into the tool, either automatically or via manual user steps.

Next, the user loads the Source Data model for the system they wish to integrate data from.

Next, the user maps from the source data model to the Semantic Database Schema, and selects options on when and how often to execute this mapping. As the Bulk Data Tool understands the nature of data exposed by the Source Data Model and Semantic Database Schema, it allows the user to draw links between the two. For example, if a source may expose the FirstName field as a String of length 20 characters, and the Business Integration Configuration exposes a First Name data property as XSD:String, the system will allow the user to map the source to this as this combination is compatible (they are both strings).

The system then updates the Provenance graph with the configuration of the Data System.

Finally, the system saves the state of the deployed Data System configuration.

If previously selected in workflow 1, the system will update the separate Provenance Graph with provenance information attached to each piece of data so ingested or served. This may include the originating source system, date/time of ingest, source and destination schema, who defined the integration job etc.

Once these workflow steps are complete, the Data System is ready to begin ingesting data from these sources when the data is either pushed into a Topic (a separate step outside this invention) or via the Bulk Data Mapping configuration. Once data is stored in the Semantic Graph Database, it is immediately available for serving via any generated API's.

### Interpretation

A number of methods have been described above. Any of these methods may be embodied in a series of instructions, which may form a computer program. These instructions, or this computer program, may be stored on a computer readable medium, which may be non-transitory. When executed, these instructions or this program cause a processor to perform the described methods.

Where an approach has been described as being implemented by a processor, this may comprise a plurality of processors. That is, at least in the case of processors, the singular should be interpreted as including the plural. Where methods comprise multiple steps, different steps or different parts of a step may be performed by different processors.

The steps of the methods have been described in a particular order for ease of understanding. However, the steps can be performed in a different order from that specified, or with steps being performed in parallel. This is the case in all methods except where one step is dependent on another having been performed.

The term “comprises”, and other grammatical forms is intended to have an inclusive meaning unless otherwise noted. That is, they should be taken to mean an inclusion of the listed components, and possibly of other non-specified components or elements.

While the present invention has been explained by the description of certain embodiments, the invention is not restricted to these embodiments. It is possible to modify these embodiments without departing from the spirit or scope of the invention.

1-12. (canceled)

13. A method for declarative generation from ontology, taxonomy and annotation models, and user configurations of same, of all data schema and deployment configurations required in a data system, comprising:
retrieving from memory a set of models comprising ontologies, taxonomies and annotation models;
displaying for a user the set of models;
receiving from the user a configuration of the ontology and taxonomy models comprising selections, removals and/or customisations;
receiving from the user a configuration of annotation models comprising selection, removal, and/or customisations;
receiving from the user an assignment of annotation model elements against ontology and taxonomy model elements;
receiving from the user a set of configuration parameters for existing data system technical systems;
reading the assigned user selections and configurations, and applying a declarative generation system to create one or more data schema, including multiple versions of said data schema, in various formats required by the various data system technical systems;
reading the assigned user selections and configurations, and applying a declarative generation system to create deployment artefacts for the data schema intended for the various technical systems; and
sending these deployment artifacts and associated data schema into various data system technical systems, and configuring these for operation.

14. The method of claim 13, wherein the ontology models comprise definitions of the meaning of data and relationships between data, and taxonomy models comprise common classification schemes that can be linked to any ontology model element and hence extend the meaning of data classified by the ontology.

15. The method of claim 13, wherein the annotation models comprise metadata statements that can be applied against any ontology or taxonomy element, with said statements comprising any combination of the following: version number; any industry classification schemes or standards; any ad-hoc grouping or tag; group membership within a nominated data schema; and type of data system technical system for deployment.

16. The method of claim 13, wherein the different ontology, taxonomy and annotation models and user configurations of said models define multiple different allowable configurations of data system data schema and deployment configurations for different types of data system technical systems, from the totality of possible configurations permitted by the models.

17. The method of claim 13, wherein the declarative generation system retrieves from memory the set of ontology, taxonomy and annotation models and user configurations, and applies the annotation model metadata statements to determine what ontology and taxonomy model elements to select and group for inclusion in different data schema, and the intended data system technical systems to instantiate these schema on.

18. The method of claim 17, wherein the declarative generation system uses a combination of custom code encoding transformation and generation rules to accord with the annotation models, and mappings between ontology languages and other computer data languages such as integration schema languages, programmatic API data schema languages, and data storage schema languages.

19. The method of claim 18, wherein the mappings are in a format selected from R2RML, SPARQL, RML, YAML, AVRO, JSON-LD, and JSON.

20. The method of claim 13, wherein the declarative generation system retrieves from memory the declaratively generated data schema and the intended data system technical systems, and generates the required deployment artifacts and sends these to the technical systems to prepare them to receive data in accordance with the meaning specified by the matching data schema.

21. The method of claim 13, wherein the types of data system technical systems may consist of: event and message based integration systems; relational, graph and other no-SQL data storage systems; programmatic API systems; and data transformation systems.

22. The method of claim 13, wherein the meaning and structure of data is preserved and made explicit across all elements of the total data system and across all data lifecycles by nature of being declaratively generated from the same source ontology, taxonomy and annotation models, irrespective of modifications and selections from said models or target technical system.

23. The method of claim 13, wherein the runtime behaviour of the data system once deployed, can be further modified by changing, adding or removing data schema through additional declarative generation steps triggered by subsequent user configuration of already deployed annotation models and associated taxonomy and ontology models.

24. The method of claim 13, wherein the data system may be extended to support new or changed data standards through addition of new annotation models applied to the ontology and taxonomy models, resulting in declarative generation of new data schema and deployment of same, without modifying or impacting existing deployed data schema within the total data system.

25. The method of claim 13, wherein the system can concurrently preserve existing deployed versions of said standards, and the user selections and customisations made to the models and resulting declaratively generated data schema, while also preserving the meaning of data across those versions within the data system.

26. The method of claim 13, wherein an ontology model that defines the meaning of provenance may be included, and the user may use a provenance annotation to select and configure what parts of the ontology and taxonomy to apply this provenance ontology model to, and the declarative generation system will build provenance into the generated data schema and deploy this into the data system technical systems.

27. The method of claim 13, wherein the meaning and structure of business instance data, technical systems configuration, and various data schema specifications, are defined through declarative generation from ontology, taxonomy and annotation models.

28. The method of claim 13, wherein the ontology and taxonomy languages are in a format selected from RDF, OWL and SPARQL.

29. The method of claim 13, wherein the generated data schema for integration technical systems are in a format selected from Apache AVRO and JSON.

30. The method of claim 13, wherein the generated programmatic API data schemas are in a format selected from JSON, YAML and OpenAPI.

31. A system implementing the method of claim 13.

32. A computer-readable medium storing instructions that, when executed by a computer, cause the computer to perform the method of claim 13.
